(19) United States
(12) Patent Application Publication
(10) Pub. No.: US 2026/0164901 A1
(43) Pub. Date: Jun. 11, 2026

(54) DISPLAY DEVICE

(71) Applicant: LG Display Co., Ltd., Seoul (KR)

(72) Inventors: Jaemin PARK, Ansan-si (KR); Sungmoo KIM, Goyang-si (KR)

(73) Assignee: LG Display Co., Ltd., Seoul (KR)

(21) Appl. No.: 19/337,512

(22) Filed: Sep. 23, 2025

(30) Foreign Application Priority Data
Dec. 9, 2024 (KR) 10-2024-0181610

(51) Int. Cl. H10H 29/855

(52) U.S. Cl. CPC H10H 29/8552

(57) ABSTRACT

A display device can include a first substrate on which a plurality of subpixels is defined. The display device also includes a plurality of light-emitting elements disposed on the first substrate and corresponding respectively to the plurality of subpixels. Further, the display device includes an anti-glare layer disposed on the plurality of light-emitting elements and having a concave-convex structure. The display device further includes a refractive layer disposed below the anti-glare layer and configured to fill a part of the concave-convex structure. In addition, the display device includes a transparent insulation layer disposed to surround a part of an upper portion of each of the plurality of light-emitting elements and configured to be in contact with the anti-glare layer and the refractive layer.

### CROSS-REFERENCE TO RELATED APPLICATIONS

This application claims priority to Korean Patent Application No. 10-2024-0181610 filed on Dec. 9, 2024, in the Republic of Korea, the entire disclosure of which is hereby expressly incorporated by reference into the present application.

### BACKGROUND

### Technical Field

The present disclosure relates to a light-emitting element and a display device including the same, and more particularly, to a display device with improved external light reflection.

### Discussion of the Related Art

As display devices used for a monitor of a computer, a TV set, a mobile phone, and the like, there are an organic light-emitting display (OLED) configured to autonomously emit, and a liquid crystal display (LCD) that requires a separate light source.

The range of application of the display devices is diversified from the monitor of the computer and the TV set to personal mobile devices, and studies are being conducted on the display devices having wide display areas and having reduced volumes and weights.

In addition, recently, a display device including a light-emitting diode (LED) has attracted attention as a next-generation display device. Because the LED is made of an inorganic material instead of an organic material, the LED is more reliable and has a longer lifespan than a liquid crystal display device or an organic light-emitting display device. In addition, the LED can be quickly turned on or off, have excellent luminous efficiency, high impact resistance, and great stability, and display high-brightness images.

### SUMMARY OF THE DISCLOSURE

An object to be achieved by the present disclosure is to provide a display device in which an anti-glare layer and a refractive layer are disposed to scatter light introduced as external light, thereby improving reflectance.

Another object to be achieved by the present disclosure is to provide a display device manufactured by a simplified process of transferring a light-emitting element onto a second substrate in a non-contact transfer manner and then bonding the second substrate with a first substrate.

Still another object to be achieved by the present disclosure is to provide a display device with excellent luminance regardless of a viewing angle.

Objects of the present disclosure are not limited to the above-mentioned objects, and other objects, which are not mentioned above, can be clearly understood by those skilled in the art from the following descriptions.

According to an aspect of the present disclosure, there is provided a display device. The display device includes a first substrate on which a plurality of subpixels is defined. The display device further includes a plurality of light-emitting elements disposed on the first substrate, corresponding respectively to the plurality of subpixels. The display device further includes an anti-glare layer disposed on the plurality of light-emitting elements and having a concave-convex structure. The display device further includes a refractive layer disposed below the anti-glare layer and configured to fill a part of the concave-convex structure. The display device further includes a transparent insulation layer disposed to surround a part of an upper portion of each of the plurality of light-emitting elements and configured to be in contact with the anti-glare layer and the refractive layer.

According to another aspect of the present disclosure, there is provided a display device. The display device includes a first substrate on which a plurality of thin-film transistors is disposed. The display device further includes a plurality of light-emitting elements disposed on the thin-film transistors. The display device further includes a second substrate on which an anti-glare layer having a concave-convex structure, a refractive layer disposed on the anti-glare layer and configured to fill a part of the concave-convex structure, and a transparent insulation layer disposed to surround a part of an upper portion of each of the plurality of light-emitting elements and configured to be in contact with the anti-glare layer and the refractive layer are sequentially disposed. The display device further includes a bonding layer configured to join the first substrate and the second substrate. The plurality of thin-film transistors and the plurality of light-emitting elements are electrically connected.

According to still another aspect of the present disclosure, there is provided a display device comprising a first substrate on which a plurality of subpixels is defined; a plurality of light-emitting elements disposed on the first substrate, corresponding respectively to the plurality of subpixels; a transparent insulation layer covering an upper surface of the light-emitting element; an anti-glare layer disposed over the plurality of light-emitting elements and covering at a first portion of the upper surface of the transparent insulation layer to form a first interface contacting with the first portion; a refractive layer disposed below the anti-glare layer and contacting a second portion of the upper surface of the transparent insulation layer to form a second interface; wherein the anti-glare layer includes a first anti-glare structure and a second anti-glare structure, wherein the first anti-glare structure corresponds to a region of the plurality of light-emitting elements on the first substrate, and the second anti-glare structure corresponds to the portion other than the region of the plurality of light-emitting elements on the first substrate.

Other detailed matters of the example embodiments of the present disclosure are included in the detailed description and the drawings.

The display device according to aspects of the present disclosure can improve external light reflectance.

In the display device according to aspects of the present disclosure, the transparent insulation layer, which has the same refractive index as the anti-glare layer, can be disposed on the light-emitting element, thereby suppressing distortion caused by refraction of light.

The process of manufacturing the display device according to aspects of the present disclosure can be simplified because the process is performed by transferring the light-emitting element in the non-contact transfer manner and then bonding the first substrate and the second substrate.

The display device according to aspects of the present disclosure can have excellent luminance regardless of the viewing angle and thus operate with low power consumption.

The effects according to aspects of the present disclosure are not limited to the above-mentioned effects, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic configuration view of a display device according to one or more embodiments of the present disclosure;

FIG. 2 is a schematic top plan view of a plurality of subpixels of the display device according to one or more embodiments of the present disclosure;

FIG. 3 is a cross-sectional view taken along line III-III′ in FIG. 2 according to an example of the present disclosure;

FIG. 4 is a graph for explaining viewing angle characteristics of the display device according to one or more embodiments of the present disclosure; and

FIGS. 5A to 5F are process flowcharts for explaining a method of manufacturing the display device according to one or more embodiments of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms such as “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated. Further, the term “can” fully encompasses all the meanings and coverages of the term “may” and vice versa.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings. All the components of each display device according to all embodiments of the present disclosure are operatively coupled and configured.

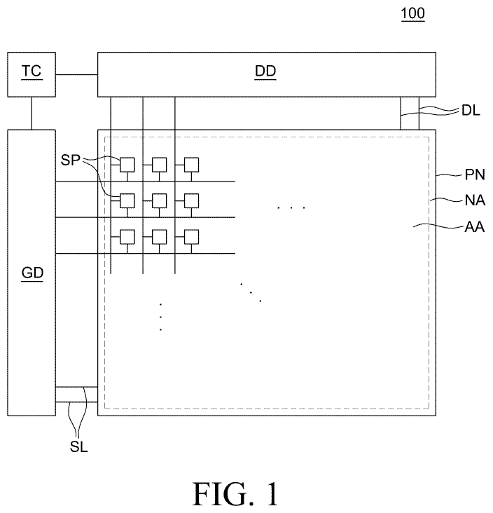

FIG. 1 is a schematic configuration view of a display device according to an embodiment of the present disclosure. For convenience of description, FIG. 1 illustrates a display panel PN, a gate driver GD, a data driver DD, and a timing controller TC among various constituent elements of a display device 100.

With reference to FIG. 1, the display device 100 includes the display panel PN including a plurality of subpixels SP, the gate driver GD configured to supply various types of signals to the display panel PN, and the timing controller TC configured to control the data driver DD, the gate driver GD, and the data driver DD.

The gate driver GD supplies a plurality of scan signals to a plurality of scan lines SL in response to a plurality of gate control signals provided from the timing controller TC. FIG. 1 illustrates that the single gate driver GD is disposed to be spaced apart from one side of the display panel PN. However, the number and arrangement of the gate driver GD are not limited thereto.

The data driver DD converts image data, which is inputted from the timing controller TC, into a data voltage by using a reference gamma voltage in response to a plurality of data control signals provided from the timing controller TC. The data driver DD can supply the converted data voltage to a plurality of data lines DL.

The timing controller TC aligns image data, which are inputted from the outside, and supplies the image data to the data driver DD. The timing controller TC can generate the gate control signals and the data control signals by using synchronizing signals, i.e., dot clock signals, data enable signals, and horizontal/vertical synchronizing signals inputted from the outside. Further, the timing controller TC can control the gate driver GD and the data driver DD by supplying the generated gate control signals and data control signals to the gate driver GD and the data driver DD.

The display panel PN is configured to display images to a user and includes the plurality of subpixels SP. In the display panel PN, a plurality of scan lines SL and a plurality of data lines DL intersect one another, and each of the plurality of subpixels SP is connected to the scan line SL and the data line DL. In addition, the plurality of subpixels SP can be respectively connected to a high-potential power line, a low-potential power line, a reference line, and the like.

The display panel PN can have a display area AA (or active area), and a non-display area NA (or non-active area) configured to surround the display area AA.

The display area AA is an area of the display device 100 in which images are displayed. The display area AA can include the plurality of subpixels SP constituting a plurality of pixels, and a circuit configured to operate the plurality of subpixels SP. The plurality of subpixels SP is minimum units that constitute the display area AA. The n subpixels SP can constitute a single pixel. A light-emitting element, a thin-film transistor for operating the light-emitting element, and the like can be disposed in each of the plurality of subpixels SP. Light emitting elements LED can be differently defined depending on the type of display panel PN. For example, in case that the display panel PN is an inorganic light-emitting display panel PN, the light-emitting element can be a light-emitting diode (LED) or a micro light-emitting diode (micro LED).

A plurality of signal lines for transmitting various types of signals to the plurality of subpixels SP are disposed in the display area AA. For example, the plurality of signal lines can include the plurality of data lines DL for supplying data voltages to the plurality of subpixels SP, and the plurality of scan lines SL for supplying gate voltages to the plurality of subpixels SP. The plurality of scan lines SL can extend in one direction in the display area AA and be connected to the plurality of subpixels SP. The plurality of data lines DL can extend in a direction different from one direction in the display area AA and be connected to the plurality of subpixels SP. In addition, a low-potential power line, a high-potential power line, and the like can be further disposed in the display area AA. However, the present disclosure is not limited thereto.

The non-display area NA can be defined as an area in which no image is displayed, i.e., an area extending from the display area AA. The non-display area NA can include link lines and pad electrodes for transmitting signals to the subpixels SP in the display area AA. Alternatively, the non-display area NA can include drive integrated circuits (ICs) such as gate driver ICs and data driver ICs.

Meanwhile, the non-display area NA can be positioned on a rear surface of the display panel PN, i.e., a surface on which the subpixel SP is not present. Alternatively, the non-display area NA can be excluded. However, the present disclosure is not limited to the configuration illustrated in the drawings.

Meanwhile, the drivers such as the gate driver GD, the data driver DD, and the timing controller TC can be connected to the display panel PN in various ways. For example, the gate driver GD can be mounted in a non-display area NA by a gate-in-panel (GIP) method or mounted between the plurality of subpixels SP by a gate-in-active area (GIA) method in a display area AA. For example, the data driver DD and the timing controller TC can be formed on a separate flexible film and a printed circuit board and electrically connected to the display panel PN by a method of bonding the flexible film and the printed circuit board to a pad electrode formed in the non-display area NA of the display panel PN. In case that the gate driver GD is mounted by the GIP method and the data driver DD and the timing controller TC transmit signals to the display panel PN through the pad electrode in the non-display area NA, it is necessary to ensure an area of the non-display area NA in order to dispose the gate driver GD and the pad electrode, which can increase a bezel.

Alternatively, in case that the gate driver GD is mounted in the display area AA by the GIA method and a side line SRL, which connects a signal line on a front surface of the display panel PN to the pad electrode on the rear surface of the display panel PN, is formed to bond the flexible film and the printed circuit board to the rear surface of the display panel PN, it is possible to minimize the non-display area NA on the front surface of the display panel PN. For example, in case that the gate driver GD, the data driver DD, and the timing controller TC are connected to the display panel PN by the above-mentioned method, a zero bezel in which the bezel is not substantially present can be implemented.

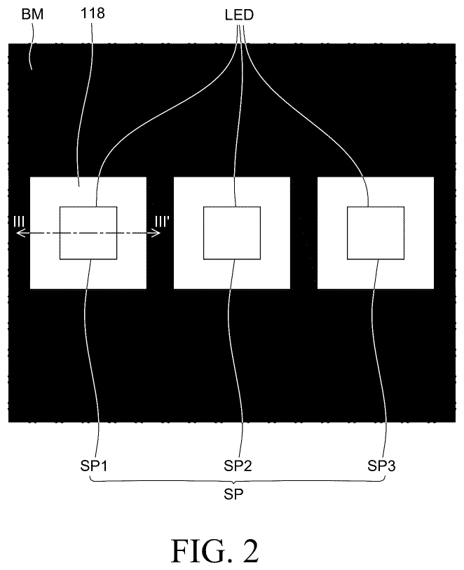

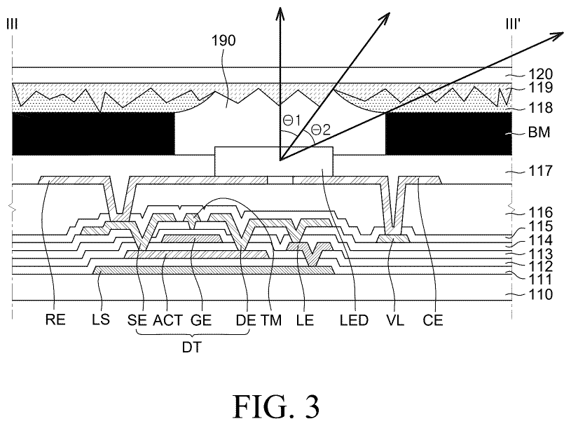

FIG. 2 is a schematic top plan view of a plurality of subpixels of the display device according to the embodiment of the present disclosure. FIG. 3 is a cross-sectional view taken along line III-III′ in FIG. 2. For convenience of description, FIG. 2 illustrates the plurality of subpixels SP, a black matrix BM, and a refractive layer 118 among various constituent elements of the display device 100.

First, with reference to FIG. 2, the plurality of subpixels SP can each include a light-emitting element LED and a pixel circuit according to various embodiments of the present disclosure and independently emit light. For example, the plurality of subpixels SP can include a first subpixel SP1, a second subpixel SP2, and a third subpixel SP3. The first subpixel SP1, the second subpixel SP2, and the third subpixel SP3 can emit light beams with different colors. However, the present disclosure is not limited thereto. For example, the first subpixel SP1 can be a red subpixel configured to emit red light, the second subpixel SP2 can be a green subpixel configured to emit green light, and the third subpixel SP3 can be a blue subpixel configured to emit blue light. However, the color of light, the configuration, and the arrangement implemented by the plurality of subpixels SP can vary in accordance with design. However, the present disclosure is not limited thereto.

With reference to FIG. 3, a first substrate 110, a buffer layer 111, a gate insulation layer 112, a first interlayer insulation layer 113, a second interlayer insulation layer 114, a passivation layer 115, a planarization layer 116, a bonding layer 117, a driving transistor DT, the light-emitting element LED, a reflective electrode RE, a conductive layer TM, a power line VL, a connection electrode CE, a light-blocking layer LS, an auxiliary electrode LE, the black matrix BM, a transparent insulation layer 190, the refractive layer 118, an anti-glare layer 119, and a second substrate 120 can be disposed in each of the plurality of subpixels SP of the display device 100 according to the embodiment of the present disclosure.

First, the first substrate 110 can be configured to support various constituent elements included in the display device 100 and made of an insulating material. For example, the first substrate 110 can be made of glass, resin, or the like. In addition, the first substrate 110 can include plastic such as polymer and can be made of a material having flexibility.

The light-blocking layer LS can be disposed on the first substrate 110. The light-blocking layer LS blocks light entering an active layer ACT of the transistor (e.g., driving transistor DT), which will be described below, from a lower side of the first substrate 110. The light-blocking layer LS can block light entering the active layer ACT of the driving transistor DT, thereby minimizing a leakage current. In some embodiments of the present invention, the light-blocking layer LS can be formed of a metal/alloy materials. For example, light-blocking layer LS can be composed of a single layer or multiple layers made of any one of molybdenum (Mo), aluminum (Al), chromium (Cr), gold (Au), titanium (Ti), nickel (Ni), neodymium (Nd), and copper (Cu), or the alloys thereof. The light-blocking layer LS made of an alloy can effectively reduce leakage current of the active layer ACT.

The buffer layer 111 can be disposed on the first substrate 110 and the light-blocking layer LS. The buffer layer 111 can reduce the permeation of moisture or impurities through the first substrate 110. For example, the buffer layer 111 can be configured as a single layer or multilayer made of silicon oxide (SiOx) or silicon nitride (SiNx). However, the present disclosure is not limited thereto. However, the buffer layer 111 can be excluded in accordance with the type of first substrate 110 or the type of transistor. However, the present disclosure is not limited thereto.

The driving transistor DT is disposed on the buffer layer 111. The driving transistor DT can include the active layer ACT, a gate electrode GE, a source electrode SE, and a drain electrode DE.

The active layer ACT can be disposed on the buffer layer 111. The active layer ACT can be made of a semiconductor material such as an oxide semiconductor, amorphous silicon, or polysilicon. However, the present disclosure is not limited thereto. The buffer layer 111 can include a contact hole for connecting the auxiliary electrode LE and the light-blocking layer LS.

The gate insulation layer 112 can be disposed on the active layer ACT. The gate insulation layer 112 is an insulation layer for insulating the active layer ACT and the gate electrode GE. The gate insulation layer 112 can include a contact hole for connecting the auxiliary electrode LE and the light-blocking layer LS. In addition, the gate insulation layer 112 can further include contact holes for connecting the source electrode SE and the drain electrode DE to the active layer ACT. For example, the gate insulation layer 112 can be configured as a single layer or multilayer made of silicon oxide (SiOx) or silicon nitride (SiNx). However, the present disclosure is not limited thereto.

The gate electrode GE can be disposed on the gate insulation layer 112. The gate electrode GE can be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The auxiliary electrode LE can be disposed on the gate insulation layer 112. The auxiliary electrode LE is an electrode that electrically connects the light-blocking layer LS, which is disposed below the buffer layer 111, to any one of the source electrode SE and the drain electrode DE on the second interlayer insulation layer 114. For example, the light-blocking layer LS can be electrically connected to any one of the source electrode SE or the drain electrode DE through the auxiliary electrode LE so as not to be operated as a floating gate, thereby minimizing a change in threshold voltage of the driving transistor DT caused by the floating light-blocking layer LS. The drawing illustrates that the light-blocking layer LS is connected to the drain electrode DE. However, the light-blocking layer LS can be connected to the source electrode SE. However, the present disclosure is not limited thereto. For instance, the light shielding layer LS can be suppressed from operating as a floating gate by electrically connecting the light blocking layer LS to a high potential power line to which a constant voltage is applied through the auxiliary electrode LE, so that fluctuations in the threshold voltage of the driving transistor DT can be minimized.

The first interlayer insulation layer 113 can be disposed on the gate electrode GE and the auxiliary electrode LE. The first interlayer insulation layer 113 can include contact holes for connecting the source electrode SE, the drain electrode DE, and the active layer ACT. The first interlayer insulation layer 113 is an insulation layer for protecting components disposed below the first interlayer insulation layer 113. The first interlayer insulation layer 113 can be configured as a single layer or multilayer made of silicon oxide (SiOx) or silicon nitride (SiNx). However, the present disclosure is not limited thereto.

The conductive layer TM can be disposed on the first interlayer insulation layer 113. The conductive layer TM can be disposed on the gate electrode GE. The conductive layer TM, together with the gate electrode GE, can constitute a storage capacitor. However, the conductive layer TM can be excluded in accordance with the embodiment.

The second interlayer insulation layer 114 can be disposed on the conductive layer TM. Contact holes, through which the source electrode SE and the drain electrode DE are connected to the active layer ACT, can be formed in the second interlayer insulation layer 114. The second interlayer insulation layer 114 can be an insulation layer for protecting components disposed below the second interlayer insulation layer 114. The second interlayer insulation layer 114 can be configured as a single layer or multilayer made of silicon oxide (SiOx) or silicon nitride (SiNx). However, the present disclosure is not limited thereto.

The source electrode SE and the drain electrode DE, which are electrically connected to the active layer ACT, can be disposed on the second interlayer insulation layer 114. The source electrode SE can be connected to the active layer ACT and the auxiliary electrode LE through the contact holes included in the gate insulation layer 112, the first interlayer insulation layer 113, and the second interlayer insulation layer 114. The drain electrode DE can be connected to the active layer ACT through the contact holes included in the gate insulation layer 112, the first interlayer insulation layer 113, and the second interlayer insulation layer 114. The source electrode SE and the drain electrode DE can each be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The power line VL can be disposed on the second interlayer insulation layer 114.

Specifically, the power line VL can be disposed to be spaced apart from the source electrode SE and the drain electrode DE and made of the same material as the source electrode SE and the drain electrode DE. However, the present disclosure is not limited thereto. The power line VL can be a low-potential power line. In this case, a low-potential voltage can be supplied to the power line VL. However, the present disclosure is not limited thereto. The power line VL can be a high-potential power line.

The power line VL can be connected to the connection electrode CE. The power line VL can be electrically connected to a first electrode of the light-emitting element LED through the connection electrode CE. Therefore, the power line VL can transmit a low-potential voltage to the connection electrode CE and the first electrode of the light-emitting element LED.

The passivation layer 115 can be disposed on the source electrode SE, the drain electrode DE, and the power line VL. The passivation layer 115 is an insulation layer for protecting components disposed below the passivation layer 115. The passivation layer 115 can be made of an inorganic material such as silicon oxide (SiOx) or silicon nitride (SiNx). However, the present disclosure is not limited thereto.

The planarization layer 116 can be disposed on the passivation layer 115. The planarization layer 116 can planarize an upper portion of the pixel circuit including the driving transistor DT. The planarization layer 116 can be configured as a single layer or multilayer and made of benzocyclobutene or an acrylic-based organic material, for example. However, the present disclosure is not limited thereto.

The reflective electrode RE and the connection electrode CE can be disposed on the planarization layer 116. The reflective electrode RE can be disposed below the light-emitting element LED and electrically connected to the light-emitting element LED. The reflective electrode RE can be configured to reflect the light, which is emitted from the light-emitting element LED, toward the upper side of the first substrate 110 and have a shape corresponding to each of the plurality of subpixels SP.

The reflective electrode RE can also be used as an electrode that reflects the light emitted from the light-emitting element LED and electrically connects the light-emitting element LED and the pixel circuit. Specifically, the reflective electrode RE can be electrically connected to the source electrode SE of the driving transistor DT through the contact holes of the passivation layer 115 and the planarization layer 116. For example, the reflective electrode RE can electrically connect the driving transistor DT and a second electrode of the light-emitting element LED.

Therefore, the reflective electrode RE can include various conductive layers in consideration of light reflection efficiency and resistance. For example, the reflective electrode RE can be made by using an opaque conductive layer, which is made of silver (Ag), aluminum (Al), molybdenum (Mo), titanium (Ti), or an alloy thereof, together with a transparent conductive layer made of indium tin oxide (ITO). However, the structure of the reflective electrode RE is not limited thereto.

The connection electrode CE can be connected to the power line VL. Specifically, the connection electrode CE can be electrically connected to the power line VL through the contact holes formed in the planarization layer 116 and the passivation layer 115.

In addition, the connection electrode CE can be connected to the first electrode of the light-emitting element LED. Therefore, the first electrode of the light-emitting element LED and the power line VL can be electrically connected through the connection electrode CE.

The connection electrode CE can overlap at least a part of the light-emitting element LED.

The connection electrode CE can be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The light-emitting element LED is disposed on the reflective electrode RE and the connection electrode CE.

The light-emitting element LED can be disposed on the connection electrode CE and electrically connected to the power line VL. Specifically, the first electrode of the light-emitting element LED and the power line VL can be electrically connected through the connection electrode CE. A connection layer having conductivity can be disposed between the first and second electrodes of the light-emitting element LED and the connection electrode CE, and the corresponding connection layer can fix the light-emitting element LED and electrically connect the first and second electrodes to the connection electrode CE that overlaps the corresponding electrodes.

Next, the bonding layer 117 can be disposed on the planarization layer 116, the reflective electrode RE, and the connection electrode CE and surround a part of a lower portion of the light-emitting element LED. In this case, the bonding layer 117 can adjoin the black matrix BM and the transparent insulation layer 190.

The bonding layer 117 can adjoin at least a part of a side surface of the light-emitting element LED. Therefore, the bonding layer 117 can fix and protect the light-emitting element LED. Specifically, the bonding layer 117 can be a layer for bonding the first substrate 110 and the second substrate 120. Specifically, as described below, the bonding layer 117 can be used to bond the first substrate 110, which is formed with the reflective electrode RE and the connection electrode CE onto the planarization layer 116, and the second substrate 120, which is formed with the black matrix BM.

The bonding layer 117 can be configured as optically clear adhesive (OCA) that can be bonded by high-energy curing using heat, ultraviolet rays, and laser beams. Alternatively, the bonding layer 117 can be configured as pressure-sensitive adhesive (PSA) that can be bonded by a method of applying physical pressure. However, the present disclosure is not limited thereto.

In the embodiment of the present disclosure, the bonding layer 117 has been described as being disposed on the connection electrode CE and adjoining at least a part of the side surface of the light-emitting element LED. However, the present disclosure is not limited thereto. The bonding layer 117 can be excluded, and a portion where the bonding layer 117 in FIG. 3 is disposed can be disposed as an empty space or occupied by air.

The black matrix BM can be disposed on the bonding layer 117. The black matrix BM is a constituent element for separating the adjacent subpixels SP. The black matrix BM can be disposed so as not to overlap the light-emitting element LED. For example, the black matrix BM includes openings that expose the light-emitting elements LED of each of the plurality of subpixels SP. The black matrix BM can be spaced apart from the plurality of light-emitting elements LED and disposed below the refractive layer 118. For example, the black matrix BM is disposed closer to the plurality of light-emitting elements LED than the refractive layer 118 and does not overlap with the plurality of light-emitting elements LED.

The black matrix BM can be made of acrylic-based resin, benzocyclobutene (BCB)-based resin, or polyimide and further include a black component. However, the present disclosure is not limited thereto.

The transparent insulation layer 190 can be disposed in the openings of the black matrix BM. For example, the transparent insulation layer 190 can be disposed between the opposing sides of the black matrix BM. The opposing sides of the black matrix BM are spaced apart from each other with the opening of the black matrix BM interposed therebetween. The transparent insulation layer 190 can be surround at least a part of a side surface and a top surface of each of the plurality of light-emitting elements LED. The transparent insulation layer 190 is a constituent element for fixing the light-emitting elements LED onto the second substrate 120 so that the light-emitting elements LED are not separated during the process of transferring the plurality of light-emitting elements LED onto the second substrate 120 to be described below.

In this case, a part of a bottom surface of the transparent insulation layer 190 can be disposed on the same plane as a bottom surface of the black matrix BM. In addition, the transparent insulation layer 190 can be in contact with a side surface of the black matrix BM, a side surface of the refractive layer 118, and the anti-glare layer 119.

The transparent insulation layer 190 can include an organic material and be made of an acrylic-based material, an epoxy-based material, a urethane-based material, a material based on silicon (Si), or the like. However, the present disclosure is not limited thereto. For instance, the transparent insulation layer 190 can be formed of a transparent photoreactive material. The transparent photoreactive material can be one of a transparent positive photoreactive material and a transparent negative photoreactive material.

The refractive layer 118 can be disposed on the transparent insulation layer 190 and the black matrix BM. The refractive layer 118, together with the anti-glare layer 119, is a constituent element for reducing external light reflectance in an area in which the black matrix BM are disposed and an area in which the black matrix BM is not disposed.

An end of the refractive layer 118 can be disposed to be closer to the plurality of light-emitting elements LED than an end of the black matrix BM to the plurality of light-emitting elements LED. In this case, the refractive layer 118 can be disposed so as not to overlap the plurality of light-emitting elements LED. In addition, the refractive layer 118 can fill a part of a concave-convex structure of the anti-glare layer 119.

An interface (e.g., the second interface) between the refractive layer 118 and the transparent insulation layer 190 can include a shape having an inclined surface. The inclined surfaces (e.g., an upper surface of the transparent insulation layer 190) of the refractive layer 118 and the transparent insulation layer 190 can be positioned in an area corresponding to an inclination angle θ2 of 30° to 60° with respect to a center of each of the plurality of light-emitting elements LED. A part of the refractive layer 118 can be in direct contact with the anti-glare layer 119. In other words, the interface (the interface is inclined relative to the upper surface of the light-emitting element LED) between the refractive layer 118 and the transparent insulation layer 190 can be disposed in a region corresponding to the inclination angle θ2 of 30° to 60° with respect to the center of each of the plurality of light-emitting elements LED. Therefore, external light, which is reflected from the area in which the black matrix BM is not disposed, can be canceled by the refraction on the refractive layer 118 and the concave-convex structure of the anti-glare layer 119 while passing through the inclined surface of the refractive layer 118. For example, the external light reflected at the position of the area corresponding to the inclination angle θ2 of 30° to 60° with respect to the center of each of the plurality of light-emitting elements LED can be scattered and canceled while passing through the high-refraction refractive layer 118, thereby reducing reflectance. Therefore, the luminance based on the viewing angle can be uniformized.

Moreover, due to presence of the interface (e.g., the first interface, the second interface) between refractive layer 118 and transparent insulation layer 190, the width of an upper surface of the transparent insulation layer 190 gradually becomes narrower as it is far away from the light-emitting element LED. In other words, the upper portion of transparent insulation layer 190 can form a tapered structure. This combined structure of the refractive layer 118, transparent insulation layer 190, and anti-glare layer 119 facilitates the convergence and regulation of emitted lights.

The anti-glare layer 119 can be disposed on the plurality of light-emitting elements LED and the black matrix BM. The anti-glare layer 119 is a constituent element that reduces interference of ambient light and suppresses reflection of external light and glare.

The anti-glare layer 119 can be disposed to be in contact with the refractive layer 118 and the transparent insulation layer 190. In addition, a part of the anti-glare layer 119 can overlap the plurality of light-emitting elements LED. In this case, the area (e.g., the first interface) in which the anti-glare layer 119 and the plurality of light-emitting elements LED overlap can be positioned in an area corresponding to an inclination angle θ1 of 0° to 30° with respect to the center of each of the plurality of light-emitting elements LED.

For example, the anti-glare layer 119 can include an organic material. The anti-glare layer 119 can include silica, polymer, and a mixture thereof. However, the present disclosure is not limited thereto. For another example, the anti-glare layer 119 can be formed by spraying a thin layer of silicon oxides onto the surface to be applied the anti-glare layer. Alternatively, a base film material can be formed, and then subjected to a surface treatment. The base film can be made one or more of materials such as colorless polyimide (CPI), polyethylene terephthalate (PET), and polyethylene naphthalate (PEN), etc.

The anti-glare layer 119 can include the concave-convex structure. In this case, the concave-convex structure can include an embossing shape, a dot shape, a barbed shape, or the like. Because the concave-convex structure only needs to have a shape with surface roughness, the shape of the concave-convex structure is not limited.

The second substrate 120 can be disposed on the anti-glare layer 119.

The second substrate 120 can be made of glass, resin, or the like. In addition, the second substrate 120 can include plastic such as polymer and can be made of a material having flexibility.

The transparent insulation layer 190, the second substrate 120, and the anti-glare layer 119 can have the same refractive index. For example, the refractive indices of the transparent insulation layer 190, the second substrate 120, and the anti-glare layer 119 can be 1.5±0.5. Because this condition is satisfied as long as distortion does not occur because of a substantial refraction effect, the present disclosure is not limited thereto.

Meanwhile, the refractive index of the refractive layer 118 can be larger than the refractive indices of the transparent insulation layer 190, the second substrate 120, and the anti-glare layer 119. The second substrate 120 can have the same refractive index as the anti-glare layer 119. Therefore, the light emitted toward the upper sides of the plurality of light-emitting elements LED can have excellent luminance without causing distortion due to refraction.

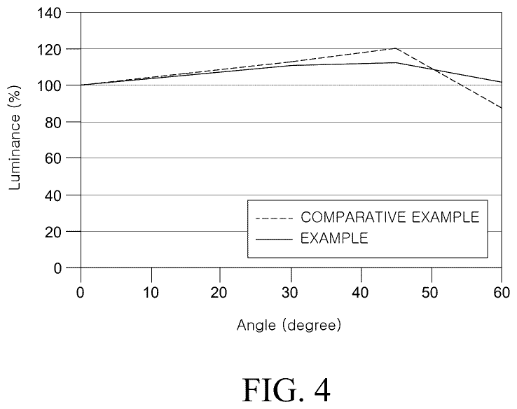

Hereinafter, viewing angle characteristics of the display device according to the embodiment of the present disclosure will be described with reference to FIG. 4.

FIG. 4 is a graph for explaining viewing angle characteristics of the display device according to the embodiment of the present disclosure. The example (“EXAMPLE”) illustrated in FIG. 4 is the display device 100 according to the embodiment of the present disclosure described with reference to FIGS. 1 to 3. The comparative example (“COMPARATIVE EXAMPLE”) illustrated in FIG. 4 is a display device in which the refractive layer 118 and the transparent insulation layer 190 are not disposed in comparison with the display device 100 according to the embodiment of the present disclosure. FIG. 4 illustrates a change in luminance with respect to a change in viewing angle for the comparative example and the example. The X-axis indicates viewing angles, and the Y-axis indicates frontal luminance, i.e., relative luminance when luminance is 100% in case that a viewing angle is 0°.

TABLE 1

| Viewing angle | Comparative Example | Example |
|---|---|---|
| (Angle(°)) | Luminance (%) | Luminance (%) |
| 0° | 100.0 | 100.0 |
| 15° | 106.2 | 105.3 |
| 30° | 113.1 | 111.0 |
| 45° | 120.1 | 112.5 |
| 60° | 88.2 | 101.4 |

With reference to FIG. 4 and Table 1, it can be ascertained that in the case of the comparative example, as the viewing angle increases, the luminance rapidly increases and then rapidly decreases, and a luminance deviation with respect to the viewing angle is relatively large. For example, it can be ascertained that in the case of the comparative example, the maximum luminance is about 120.1% at a viewing angle of 45°, the minimum luminance is about 88.2% at a viewing angle of 60°, and a luminance deviation is about 31.9%.

In contrast, it can be ascertained that in the case of the example, as the viewing angle increases, the luminance gently increases and then gently decreases, and a luminance deviation with respect to the viewing angle is relatively small. For example, it can be ascertained that in the case of the example, the maximum luminance is about 112.5% at a viewing angle of 45°, the minimum luminance is 100% at a viewing angle of 0°, and a luminance deviation is about 12.5%.

The display device 100 according to the embodiment of the present disclosure exhibits viewing angle characteristics similar to those of the comparative example at a viewing angle corresponding to the inclination angle θ1 of 0° to 30° with respect to the center of each of the plurality of light-emitting elements LED, but the emitted light is scattered at a viewing angle corresponding to the inclination angle θ2 of 30° to 60° with respect to the center of each of the plurality of light-emitting elements LED, such that the amount of change in luminance decreases in comparison with the comparative example. Therefore, in the display device 100 according to the embodiment of the present disclosure, the luminance deviation with respect to the viewing angle can decrease, thereby improving the viewing angle characteristics of the display device 100.

In general, even though the display device includes the black matrix for suppressing external light reflection, there is a problem in that a part of light is reflected even by the black matrix. In addition, it is necessary to improve external light reflectance even in the area in which the black matrix is not disposed. In addition, even though anti-glare surface treatment is performed to improve the reflection phenomenon caused by external light reflection, there is a problem in that an effect of a lens being disposed occurs during the anti-glare surface treatment, and the pixel is distorted and visually recognized.

In the display device 100 according to the embodiment of the present disclosure, the refractive layer 118 can be disposed between the black matrix BM and the anti-glare layer 119, thereby improving the external light reflectance. In particular, in case that external light is introduced into the display device 100 from the outside, the external light passes through the anti-glare layer 119 and the refractive layer 118, such that the external light can be reflected by the concave-convex structure and canceled by the refraction implemented by the high-refraction material, thereby improving the reflectance. In this case, similarly, the reflectance of external light reflected by the black matrix BM can also be reduced.

In addition, in the display device 100 according to the embodiment of the present disclosure, in the area in which the black matrix BM is not disposed, the refractive layer 118 is disposed so as not to overlap the light-emitting element LED, and the transparent insulation layer 190 is disposed above the light-emitting element LED. In this case, the transparent insulation layer 190 can have the same refractive index as the anti-glare layer 119, thereby suppressing distortion caused by refraction. Therefore, the display device 100 according to the embodiment of the present disclosure can suppress the phenomenon in which the pixel is distorted and visually recognized.

In addition, in the display device 100 according to the embodiment of the present disclosure, the refractive layer 118 is disposed so as not to overlap the light-emitting element LED in the area in which the black matrix BM is not disposed, such that the reflected external light is scattered by the refractive layer 118 and canceled by the concave-convex structure of the anti-glare layer 119, thereby improving the external light reflectance. Further, the light is emitted without being refracted in the area that overlaps the plurality of light-emitting elements LED, and the emitted light is scattered in the area that does not overlap the plurality of light-emitting elements LED, such that a luminance deviation occurring between the area, which overlaps the light-emitting element LED, and the area, which does not overlap the light-emitting element LED, can be reduced, thereby improving the luminance uniformity. Therefore, the display device 100 according to the embodiment of the present disclosure can have excellent luminance regardless of the viewing angle and thus operate with low power consumption.

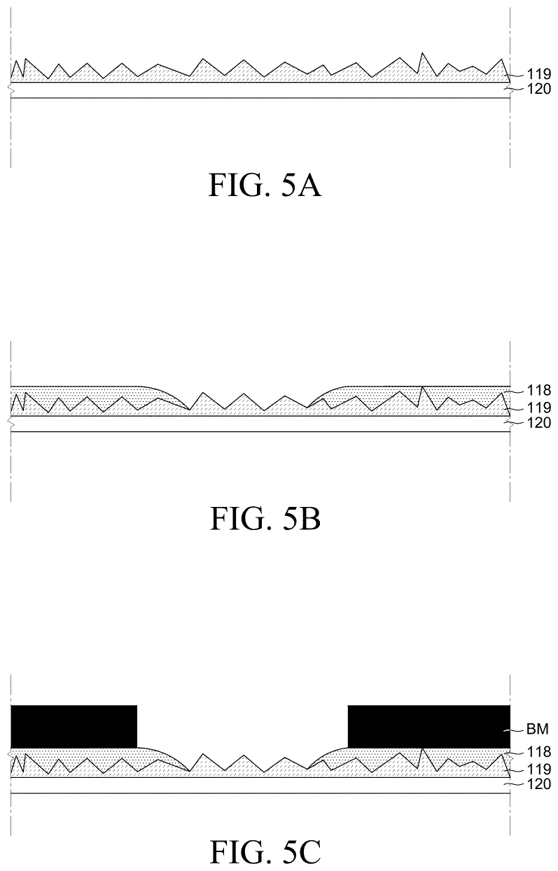

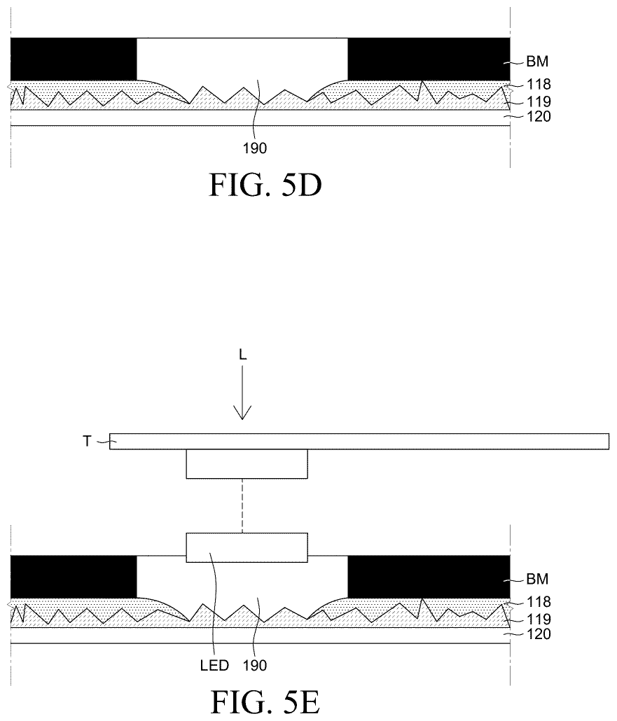

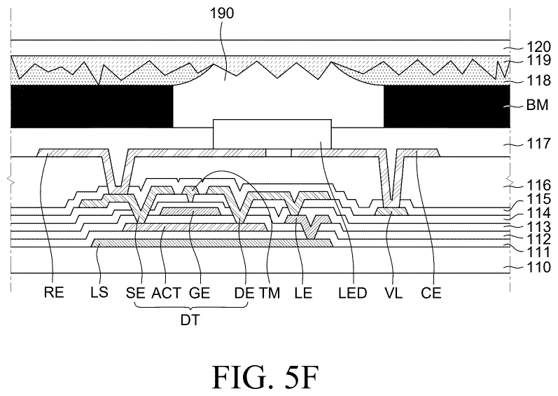

FIGS. 5A to 5F are process flowcharts for explaining a method of manufacturing the display device according to the embodiment of the present disclosure. Particularly, FIGS. 5A to 5E illustrate a process performed before the first substrate 110 and the second substrate 120 are joined, i.e., a process of transferring the light-emitting element LED onto the second substrate 120.

With reference to FIG. 5A, the anti-glare layer 119 is formed on the second substrate 120. In this case, the anti-glare layer 119 can be formed by attaching a sheet-like film or coating. However, the present disclosure is not limited thereto.

For example, the anti-glare layer 119 can have the concave-convex structure. In this case, the concave-convex structure can include an embossing shape, a dot shape, a barbed shape, or the like. Because the concave-convex structure only needs to have a shape with surface roughness, the shape of the concave-convex structure is not limited. In some manufacturing process, the anti-glare layer 119 can be formed by spraying a thin layer of silicon oxides onto the surface to be applied the anti-glare layer to form a natural uneven surface. Alternatively, a base film material can be formed, and then subjected to a surface treatment to form a regular bumpy surface. The base film can be made one or more of materials such as colorless polyimide (CPI), polyethylene terephthalate (PET), and polyethylene naphthalate (PEN), etc.

With reference to FIG. 5B, the refractive layer 118 is formed on the anti-glare layer 119. In this case, the refractive layer 118 can be formed to fill a part of the concave-convex structure of the anti-glare layer 119. In addition, one end of the refractive layer 118 can have a shape having an inclined surface. Here, the interface between the refractive layer 118 and the anti-glare layer 119 can be continuous and uninterrupted, which helps to evenly eliminate external reflected light.

With reference to FIG. 5C, the black matrix BM is formed on the refractive layer 118. There can be the area in which the black matrix BM is not disposed. The light-emitting element LED can be positioned while corresponding to the area in which the black matrix BM is not disposed.

With reference to FIG. 5D, the transparent insulation layer 190 is formed between the opposing sides of the black matrix BM. The transparent insulation layer 190 is an insulation layer for fixing the transferred light-emitting element LED.

With reference to FIG. 5E, the light-emitting element LED is transferred onto the second substrate 120 by emitting laser beams L to a temporary substrate T to which the plurality of light-emitting elements LED is attached. In this case, a part of the light-emitting element LED can be fixedly inserted into the transparent insulation layer 190.

With reference to FIG. 5F, the display device 100 can be formed by connecting the electrodes of the light-emitting elements LED by joining the first substrate 110 and the second substrate 120. In this case, the first substrate 110 and the second substrate 120 can be joined by the bonding layer 117, and the light-emitting element LED fixedly inserted by the transparent insulation layer 190 can be electrically connected to the reflective electrode RE and the connection electrode CE without swaying.

In general, the process of transferring the light-emitting element needs to perform a plurality of stamp transfer processes to transfer the light-emitting element for each subpixel by using an adhesive stamp made of a material such as PDMS, which complicates the manufacturing process.

In the method of manufacturing the display device 100 according to the embodiment of the present disclosure, the plurality of light-emitting elements LED can be transferred in a non-contact transfer manner, and then the first substrate 110 and the second substrate 120 are joined, thereby simplifying the manufacturing process. Specifically, the plurality of light-emitting elements LED are transferred in the non-contact transfer manner by the single process onto the second substrate 120 on which the black matrix BM, the refractive layer 118, the anti-glare layer 119, and the transparent insulation layer 190 are sequentially disposed, the plurality of light-emitting elements LED are fixedly inserted into the transparent insulation layer 190, and the second substrate 120, to which the plurality of light-emitting elements LED are fixed, and the first substrate 110, on which the driving transistor DT is disposed, are joined, such that the display device 100 can be manufactured. Therefore, in the display device 100 according to the embodiment of the present disclosure, the plurality of light-emitting elements LED can be transferred in a non-contact transfer manner without performing the plurality of stamp transfer processes for each subpixel, thereby simplifying the process of manufacturing the display device 100. Further, the simplified process of manufacturing the display device 100 of the present disclosure can reduce process costs.

The example embodiments of the present disclosure can also be described as follows:

According to an aspect of the present disclosure, there is provided a display device. The display device includes a first substrate on which a plurality of subpixels is defined. The display device further includes a plurality of light-emitting elements disposed on the first substrate, corresponding respectively to the plurality of subpixels. The display device further includes an anti-glare layer disposed on the plurality of light-emitting elements and having a concave-convex structure. The display device further includes a refractive layer disposed below the anti-glare layer and configured to fill a part of the concave-convex structure. The display device further includes a transparent insulation layer disposed to surround a part of an upper portion of each of the plurality of light-emitting elements and configured to be in contact with the anti-glare layer and the refractive layer.

The anti-glare layer can overlap the plurality of light-emitting elements, and the refractive layer may not overlap the plurality of light-emitting elements.

The display device can further comprises a black matrix spaced apart from the plurality of light-emitting elements and disposed below the refractive layer. The black matrix includes openings exposing the light-emitting elements of each of the plurality of subpixels. The transparent insulation layer can be disposed in the openings of the black matrix and surround at least a part of a side surface and a top surface of each of the plurality of light-emitting elements.

A part of a bottom surface of the transparent insulation layer can be disposed on the same plane as a bottom surface of the black matrix.

The display device can further comprises a bonding layer disposed to surround a part of a lower portion of each of the plurality of light-emitting elements and configured to be in contact with the black matrix and the transparent insulation layer.

An end of the refractive layer can be disposed closer to the plurality of light-emitting elements than an end of the black matrix to the plurality of light-emitting elements.

The transparent insulation layer can be in contact with a side surface of the black matrix, a side surface of the refractive layer, and the anti-glare layer.

A refractive index of the refractive layer can be larger than a refractive index of the transparent insulation layer and a refractive index of the anti-glare layer.

The refractive index of the transparent insulation layer and the refractive index of the anti-glare layer can be equal to each other.

The display device can further comprises a second substrate disposed on the anti-glare layer. The second substrate can have the same refractive index as the anti-glare layer.

According to another aspect of the present disclosure, there is provided a display device. The display device includes a first substrate on which a plurality of thin-film transistors is disposed. The display device further includes a plurality of light-emitting elements disposed on the thin-film transistors. The display device further includes a second substrate on which an anti-glare layer having a concave-convex structure, a refractive layer disposed on the anti-glare layer and configured to fill a part of the concave-convex structure, and a transparent insulation layer disposed to surround a part of an upper portion of each of the plurality of light-emitting elements and configured to be in contact with the anti-glare layer and the refractive layer are sequentially disposed. The display device further includes a bonding layer configured to join the first substrate and the second substrate. The plurality of thin-film transistors and the plurality of light-emitting elements are electrically connected.

The display device can further comprises a black matrix disposed closer to the plurality of light-emitting elements than the refractive layer and spaced apart from the plurality of light-emitting elements. The black matrix includes openings exposing each of the plurality of light-emitting elements. The transparent insulation layer can be disposed in the openings of the black matrix and surround at least a part of a side surface and a top surface of each of the plurality of light-emitting elements.

A part of the transparent insulation layer and the black matrix can be disposed on the same plane.

The transparent insulation layer can be in contact with a side surface of the black matrix, a side surface of the refractive layer, and the anti-glare layer.

An end of the refractive layer can be disposed closer to the plurality of light-emitting elements than an end of the black matrix to the plurality of light-emitting elements.

A refractive index of the refractive layer can be larger than a refractive index of the transparent insulation layer and a refractive index of the anti-glare layer.

The refractive index of the transparent insulation layer and the refractive index of the anti-glare layer can be equal to each other.

According to still another aspect of the present disclosure, there is provided a display device comprising: a first substrate on which a plurality of subpixels is defined; a plurality of light-emitting elements disposed on the first substrate, corresponding respectively to the plurality of subpixels; a transparent insulation layer covering an upper surface of the light-emitting element; an anti-glare layer disposed over the plurality of light-emitting elements and covering at a first portion of the upper surface of the transparent insulation layer to form a first interface contacting with the first portion; a refractive layer disposed below the anti-glare layer and contacting a second portion of the upper surface of the transparent insulation layer to form a second interface; wherein the anti-glare layer includes a first anti-glare structure and a second anti-glare structure, wherein the first anti-glare structure corresponds to a region of the plurality of light-emitting elements on the first substrate, and the second anti-glare structure corresponds to the portion other than the region of the plurality of light-emitting elements on the first substrate.

The first interface is positioned in a region corresponding to an inclination angle (θ1) of 0° to 30° relative to the center of each of the plurality of light-emitting elements.

The second interface is positioned in a region corresponding to an inclination angle (θ2) of 30° to 60° relative to the center of each of the plurality of light-emitting elements.

The first interface and the second interface are connected to each other and are continuous and uninterrupted.

The first interface and the second interface are uneven, and the second interface is inclined.

The first interface and the second interface are configured such that a width of an upper surface of the transparent insulation layer gradually becomes narrower as it is far away from the light-emitting element.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure.

What is claimed is:

1. A display device comprising:
a first substrate on which a plurality of subpixels is defined;
a plurality of light-emitting elements disposed on the first substrate, and corresponding respectively to the plurality of subpixels;
an anti-glare layer disposed on the plurality of light-emitting elements and having a concave-convex structure;
a refractive layer disposed below the anti-glare layer and configured to fill a part of the concave-convex structure of the anti-glare layer; and
a transparent insulation layer disposed to surround a part of an upper portion of each of the plurality of light-emitting elements, and configured to be in contact with the anti-glare layer and the refractive layer.

2. The display device of claim 1, wherein the anti-glare layer overlaps the plurality of light-emitting elements, and the refractive layer does not overlap the plurality of light-emitting elements.

3. The display device of claim 1, further comprising:
a black matrix spaced apart from the plurality of light-emitting elements and disposed below the refractive layer, the black matrix including openings for exposing the plurality of light-emitting elements corresponding to the plurality of subpixels,
wherein the transparent insulation layer is disposed in the openings of the black matrix and surrounds at least a part of a side surface and a top surface of each of the plurality of light-emitting elements.

4. The display device of claim 3, wherein a part of a bottom surface of the transparent insulation layer is disposed on a same plane as a bottom surface of the black matrix.

5. The display device of claim 3, further comprising:
a bonding layer disposed to surround a part of a lower portion of each of the plurality of light-emitting elements, and configured to be in contact with the black matrix and the transparent insulation layer.

6. The display device of claim 3, wherein an end of the refractive layer is disposed closer to the plurality of light-emitting elements than an end of the black matrix to the plurality of light-emitting elements.

7. The display device of claim 6, wherein the end of the refractive layer is closer to the plurality of light emitting elements with respect to the black matrix, but does not overlap an edge of the plurality of light emitting elements.

8. The display device of claim 3, wherein the transparent insulation layer is in contact with a side surface of the black matrix, a side surface of the refractive layer, and the anti-glare layer.

9. The display device of claim 1, wherein a refractive index of the refractive layer is larger than each of a refractive index of the transparent insulation layer and a refractive index of the anti-glare layer.

10. The display device of claim 9, wherein the refractive index of the transparent insulation layer and the refractive index of the anti-glare layer are equal to each other.

11. The display device of claim 1, further comprising:
a second substrate disposed on the anti-glare layer,
wherein the second substrate has a same refractive index as the anti-glare layer.

12. A display device comprising:
a first substrate on which thin-film transistors are disposed;
a plurality of light-emitting elements disposed on the thin-film transistors;
a second substrate on which an anti-glare layer having a concave-convex structure, a refractive layer disposed on the anti-glare layer and configured to fill a part of the concave-convex structure, and a transparent insulation layer disposed to surround a part of an upper portion of each of the plurality of light-emitting elements and configured to be in contact with the anti-glare layer and the refractive layer are disposed; and
a bonding layer configured to join the first substrate and the second substrate,
wherein the thin-film transistors and the plurality of light-emitting elements are electrically connected.

13. The display device of claim 12, further comprising:
a black matrix disposed closer to the plurality of light-emitting elements than the refractive layer and spaced apart from the plurality of light-emitting elements, the black matrix including openings for exposing the plurality of light-emitting elements,
wherein the transparent insulation layer is disposed in the openings of the black matrix and surrounds at least a part of a side surface and a top surface of each of the plurality of light-emitting elements.

14. The display device of claim 13, wherein a part of the transparent insulation layer and the black matrix are disposed on a same plane.

15. The display device of claim 13, wherein the transparent insulation layer is in contact with a side surface of the black matrix, a side surface of the refractive layer, and the anti-glare layer.

16. The display device of claim 13, wherein an end of the refractive layer is disposed closer to the plurality of light-emitting elements than an end of the black matrix to the plurality of light-emitting elements.

17. The display device of claim 16, wherein the end of the refractive layer is closer to the plurality of light emitting elements with respect to the black matrix, but does not overlap an edge of the plurality of light emitting elements.

18. The display device of claim 12, wherein a refractive index of the refractive layer is larger than each of a refractive index of the transparent insulation layer and a refractive index of the anti-glare layer.

19. The display device of claim 18, wherein the refractive index of the transparent insulation layer and the refractive index of the anti-glare layer are equal to each other.

20. A display device comprising:
a first substrate on which a plurality of subpixels is defined;
a plurality of light-emitting elements disposed on the first substrate, and corresponding respectively to the plurality of subpixels;
a transparent insulation layer covering an upper surface of one of the plurality of light-emitting elements;
an anti-glare layer disposed on the plurality of light-emitting elements, and covering a first portion of an upper surface of the transparent insulation layer to form a first interface contacting with the first portion; and
a refractive layer disposed below the anti-glare layer, and contacting a second portion of the upper surface of the transparent insulation layer to form a second interface,
wherein the anti-glare layer includes a first anti-glare structure and a second anti-glare structure, and
wherein the first anti-glare structure corresponds to a region of the plurality of light-emitting elements on the first substrate, and the second anti-glare structure corresponds to a portion other than the region of the plurality of light-emitting elements on the first substrate.

21. The display device according to claim 20,
wherein the first interface is positioned in a region corresponding to a first inclination angle of 0° to 30° relative to a center of each of the plurality of light-emitting elements, and
wherein the second interface is positioned in a region corresponding to a second inclination angle of 30° to 60° relative to the center of each of the plurality of light-emitting elements.

22. The display device according to claim 20, wherein the first interface and the second interface are connected to each other and are continuous and uninterrupted.

23. The display device according to claim 20, wherein the first interface and the second interface are uneven, and the second interface is inclined.

24. The display device according to claim 20, wherein the first interface and the second interface are configured so that a width of the upper surface of the transparent insulation layer gradually becomes narrower away from the one of the plurality of light-emitting elements.
